(19) United States
(12) Patent Application Publication
(10) Pub. No.: US 2015/0229275 A1
(43) Pub. Date: Aug. 13, 2015

(54) SEMICONDUCTOR DEVICE HAVING AN AMPLIFYING CIRCUIT

(71) Applicants: Kenji Asaki, Tokyo (JP); Miku Shiokawa, Tokyo (JP); Tetsuya Arai, Tokyo (JP)

(72) Inventors: Kenji Asaki, Tokyo (JP); Miku Shiokawa, Tokyo (JP); Tetsuya Arai, Tokyo (JP)

(21) Appl. No.: 14/422,349

(22) PCT Filed: Aug. 19, 2013
(86) PCT No.: PCT/JP2013/072633

§ 371 Date: Feb. 18, 2015

(30) Foreign Application Priority Data
Aug. 20, 2012 (JP) 2012-181488

(51) Int. Cl. H03F 1/02; H03F 3/45

(52) U.S. Cl. CPC H03F 1/0211; H03F 3/45076; H03F 2200/231; H03F 2203/45112

(57) ABSTRACT

A semiconductor device includes a voltage comparing circuit, an amplifying circuit and a control circuit. The voltage comparing circuit includes first and second transistors that are coupled in a differential manner to compare first and second input voltages. The amplifying circuit amplifies an output voltage of the voltage comparing circuit to produce an amplified signal and holds the amplified signal. The control circuit is configured, when activated, to cut off a current path though which a current flows from the amplifying circuit. The current path includes a serial connection of the first and second transistors.

This application is based upon and claims the benefit of priority from Japanese patent application No. 2012-181488, filed on Aug. 20, 2012, the disclosure of which is incorporated herein in its entirety by reference.

### TECHNICAL FIELD

The present invention relates to semiconductor device, in particular, to those having an amplifying circuit.

### BACKGROUND ART

JP2002-344304A publication exemplifies semiconductor devices having a differential amplifying circuit.

For example, as shown in FIG. 1, a differential amplifying circuit, which compares input voltages Vip and Vim and controls output voltages Vop and Vom based on the compared result, is known.

### SUMMARY OF INVENTION

The present inventors have recognized that the current consumption of this type differential amplifying circuit is adversely large. Next, with reference to FIG. 1, this problem will be described.

In FIG. 1, differential amplifying circuit 100 is a dynamic amplifier. When a value is updated in the dynamic amplifier, the dynamic amplifier needs to be pre-charged. After a value is decided, the current consumption of the dynamic amplifier decreases.

Differential amplifying circuit 100 includes voltage comparing circuit 101, amplifying circuit 102, pre-charger 103, and inverters I04 and I05.

Voltage comparing circuit 101 includes NMOS transistors TA, TB, and L1. Transistors TA and TB are differentially connected to a current source. Transistor L1 is located between the connected point of transistors TA and TB and the ground. Input voltage Vim is supplied to transistor TA. Input voltage Vip is supplied to transistor TB. Transistors TA and TB are coupled in a differential manner to compare input voltages Vim and Vip. Voltage comparing circuit 101 outputs a comparison result of input voltages Vim and Vip to terminals A and B.

Amplifying circuit 102 includes PMOS transistors T1 and T2 and NMOS transistors T3, T4, and T5. Amplifying circuit 102 amplifies an output voltage of voltage comparing circuit 101 that is the comparison result to produce an amplified comparison result. In the following, “amplified comparison result” is also denoted by “compared result”. Amplifying circuit 102 holds the compared result. The compared result is also denoted by “amplified signal”.

Pre-charger 103 that is a T type PMOS pre-charger includes PMOS transistors TP1 to TP3 and executes a pre-charge operation.

Next, the operation of differential amplifying circuit 100 will be described.

When the signal levels of both sense start signal SENT1a and amplifier activation signal SENT2a become the “H” level, pre-charger 103 is turned off, transistor T5 is turned on, and transistor L1 is turned ON. As a result, the potential between input voltage Vim and input voltage Vip is amplified and thereby the amplified potential occurs between terminal A and terminal B.

Immediately after voltage Vxm at terminal A and voltage Vxp at terminal B exceed a logical threshold of amplifying circuit 102, these voltages are latched and they are settled. The voltage at terminal A is amplified by inverter 104 and output as output voltage Vom, whereas the voltage at terminal B is amplified by inverter I05 and output so as to output voltage Vop.

Thereafter, when the signal level of amplifier activation signal SENT2a becomes the “L” level, transistor L1 is turned off and thereby the current that flows in transistor L1 is shut off.

However, even if the current that flows in transistor L1 is shut off, if input voltage Vim and input voltage Vip are equal to or higher than Vth (threshold voltage) of transistors TA and TB and if input voltage Vim is not equal to input voltage Vip, a current flows in path C represented by a dotted line shown in FIG. 1 (a path that leads from transistor T1 to transistor T5 through transistor TA, transistor TB, and transistor T4). This current causes the current consumption of differential amplifying circuit 100 to increase.

In one embodiment, there is provided a semiconductor device that includes: a voltage comparing circuit including first and second transistors that are coupled in a differential manner to compare first and second input voltages; an amplifying circuit amplifying an output voltage of the voltage comparing circuit to produce an amplified signal and holding the amplified signal; and a control circuit configured, when activated, to cut off a current path though which a current flows from the amplifying circuit, the current path including a serial connection of the first and second transistors.

In another embodiment, there is provided a semiconductor device that includes: a voltage comparing circuit including first and second transistors that are coupled in a differential manner to compare first and second input voltages; an amplifying circuit amplifying an output voltage of the voltage comparing circuit to produce an amplified signal and holding the amplified signal; and a switch circuit inserted in series with at least one of the first and second transistors and configured, when turned OFF, to cut off a current flowing into the at least one of the first and second transistors.

In another embodiment, there is provided a semiconductor device that includes: a voltage comparing circuit including first and second transistors that are coupled in a differential manner to compare first and second input voltages; an amplifying circuit amplifying an output voltage of the voltage comparing circuit to produce an amplified signal and holding the amplified signal; and a first control circuit configured, when activated, to supply a gate of the first transistor with a cut-off voltage which turns each of the first and second transistors OFF and, when inactivated, to supply the gate of the first transistor with the first input voltage.

### BRIEF DESCRIPTION OF DRAWINGS

The above features and advantages of the present invention will be more apparent from the following description of certain preferred embodiments taken in conjunction with the accompanying drawings, in which:

FIG. 1 is a schematic diagram showing a differential amplifying circuit according to the related art;

FIG. 2 is a schematic diagram showing semiconductor device 200 according to a first embodiment of the present invention;

FIG. 3 is a schematic diagram showing semiconductor device 200A according to a second embodiment of the present invention;

FIG. 4 is a schematic diagram showing semiconductor device 200B according to a third embodiment of the present invention;

FIG. 5 is a schematic diagram showing semiconductor device 200C according to a fourth embodiment of the present invention;

FIG. 6 is a schematic diagram showing differential amplifier control circuit 107A;

FIG. 7 is an operation waveform diagram describing the operation of differential amplifier control circuit 107A that is used as differential amplifier control circuit 107;

FIG. 8 is schematic diagram showing differential amplifier control circuit 107B;

FIG. 9 is an operation waveform diagram describing the operation of differential amplifier control circuit 107B that is used as differential amplifier control circuit 107;

FIG. 10 is a schematic diagram showing differential amplifier control circuit 107C;

FIG. 11 is an operation waveform diagram describing the operation of differential amplifier control circuit 107C that is used as differential amplifier control circuit 107;

FIG. 12 is a schematic diagram showing differential amplifier control circuit 107D;

FIG. 13 is an operation waveform diagram describing the operation of differential amplifier control circuit 107D that is used as differential amplifier control circuit 107;

FIG. 14 is a schematic diagram showing differential amplifier control circuit 107E;

FIG. 15 is an operation waveform diagram describing the operation of differential amplifier control circuit 107E that is used as differential amplifier control circuit 107;

FIG. 16 is a schematic diagram showing differential amplifier control circuit 107F;

FIG. 17 is a schematic diagram showing differential amplifier control circuit 107G;

FIG. 18 is a schematic diagram showing differential amplifier control circuit 107H;

FIG. 19 is a schematic diagram showing differential amplifier control circuit 107H;

FIG. 20 is an operation waveform diagram describing the operation of differential amplifier control circuit 107I that is used as differential amplifier control circuit 107;

FIG. 21 is a schematic diagram showing an example of semiconductor device 200Y; and

FIG. 22 is a schematic diagram showing output impedance control circuit 13.

### DESCRIPTION OF EMBODIMENTS

The invention will be now described herein with reference to illustrative embodiments. Those skilled in the art will recognize that many alternative embodiments can be realized using the teachings of the present invention and that the invention is not limited to the embodiments illustrated for explanatory purposes.

### First Embodiment

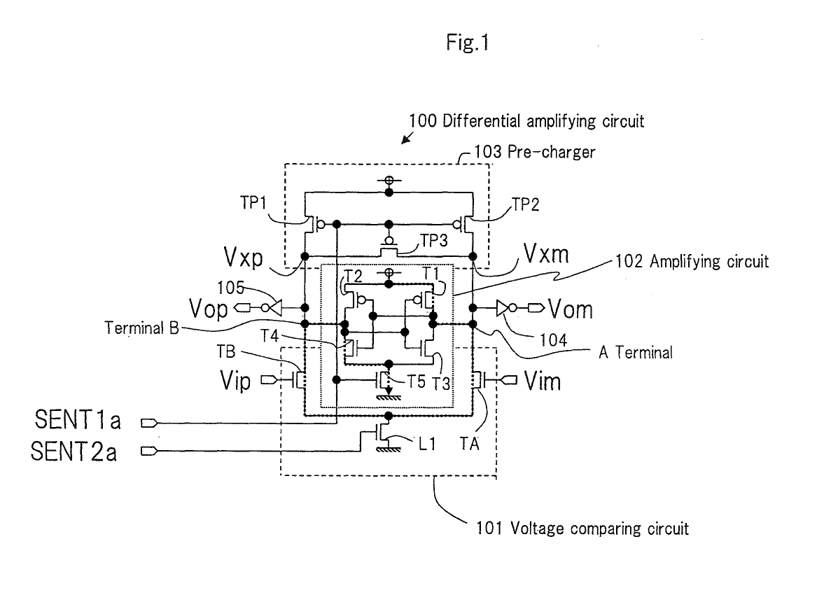

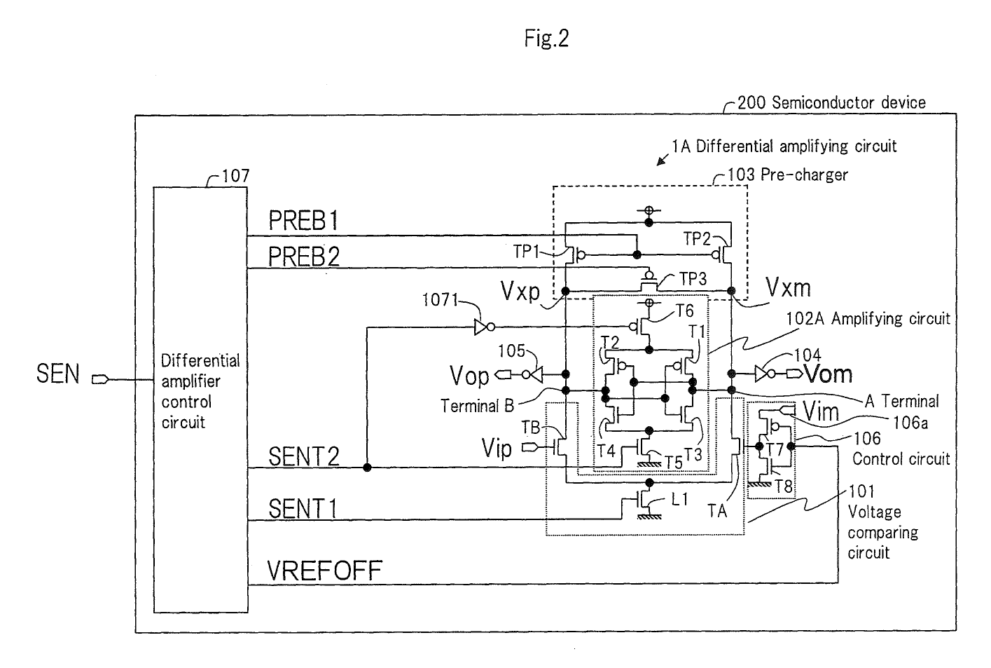

FIG. 2 is a schematic diagram showing semiconductor device 200 according to a first embodiment of the present invention. In FIG. 2, similar structures to those in FIG. 1 are denoted by similar reference numerals and their description will be omitted.

In FIG. 2, semiconductor device 200 that is, for example, a DRAM includes differential amplifying circuit 1A. It should be noted that the semiconductor device including differential amplifying circuit 1A may be a semiconductor device other than a DRAM (for example, an SRAM, a PRAM, or a flash memory).

Differential amplifying circuit 1A includes voltage comparing circuit 101, amplifying circuit 102A, pre-charger 103, inverters I04 and I05, and control circuit 106. In other words, differential amplifying circuit 1A is different from differential amplifying circuit 100 shown in FIG. 1 in that the former includes amplifying circuit 102A instead of amplifying circuit 102 that has control circuit 106.

Differential amplifying circuit 1A is controlled by differential amplifier control circuit 107.

Input voltage Vim is an example a first input voltage; and input voltage Vip is an example of a second input voltage. Transistor TA is an example of a first transistor; and transistor TB is an example of a second transistor.

Next, differential amplifying circuit 1A will be described focused on the differences with differential amplifying circuit 100.

Amplifying circuit 102A is an amplifying circuit in which amplifying circuit 102 shown in FIG. 1 also includes PMOS transistor T6. Each of Transistors T5, T6 and L1 functions as a current source.

Control circuit 106 is an example of circuit means, a first control circuit, a first inverter circuit and a circuit.

Control circuit 106 uses input voltage Vim for a power supply voltage and is connected to the gate of transistor TA. After amplifying circuit 102A substantially holds the compared result of voltage comparing circuit 101, control circuit 106 shuts off current path (route) C of a current that flows in amplifying circuit 102A through transistor TA and transistor TB that are connected in series.

Control circuit 106 includes input terminal 106a for input voltage Vim, PMOS transistor T7, and NMOS transistor T8.

Transistor T7 is an example of a third transistor; and transistor T8 is an example of a fourth transistor.

The source of transistor T7 is connected to input terminal 106a; and the drain of transistor T7 is connected to the gate of transistor TA. The source of transistor T8 is connected to the ground. The drain of transistor T8 is connected to the gate of transistor TA. The gate of transistor TA is an example of a control electrode of the first transistor. The ground is an example of a supply line for a cutoff voltage. The source of transistor T7 is an example of a power node of the first inverter circuit. A combination of the drain of transistor T7 and the drain of transistor T8 is an example of an output node of the first inverter circuit. A combination of the gate of the transistor T7 and the gate of transistor T8 is an example of an input node of the first inverter circuit.

Differential amplifier control circuit 107 generates sense start signal SENT1, amplifier activation signal SENT2, and control signals PREB1, PREB2, and VREFOFF corresponding to sense start signal SEN. Differential amplifier control circuit 107 controls differential amplifying circuit 1A corresponding to sense start signal SENT1, amplifier activation signal SENT2, and control signals PREB1, PREB2, and VREFOFF. Amplifier activation signal SENT2 is also supplied to the gate of transistor T6 through inverter I071.

Thus, semiconductor device 200 includes: voltage comparing circuit 100 that including first and second transistors TA and TB which are coupled in a differential manner to compare first and second input voltages Vim and Vip; amplifying circuit 102A that amplifies the output voltage of voltage comparing circuit 100 to produce the amplified signal and holds the amplified signal; and control circuit 106 configured, when activated, to cut off a current path though which a current flows from the amplifying circuit 102A, the current path including a serial connection of the first and second transistors TA and TB.

Control circuit 106 cuts off the current path after amplifying circuit 102A substantially holds the amplified signal.

Control circuit 106 includes switch TA inserted in the current path. Switch TA is turned OFF after amplifying circuit 102A substantially holds the amplified signal.

Control circuit 106 supplies the gate of the first transistor TA with a cut-off voltage which turns first transistor TA OFF after amplifying circuit 102A substantially holds the amplified signal.

First control circuit 106 is configured, when activated, to supply the gate of the first transistor TA with the cut-off voltage which turns each of the first and second transistors TA and TB OFF and, when inactivated, to supply the gate of the first transistor TA with the first input voltage Vim.

The power node of the first inverter circuit 106 is supplied with the first input voltage Vim. The input node of the first inverter circuit 106 is supplied with control signal VREFOFF. The output node of the first inverter circuit 106 is coupled to the gate of the first transistor TA.

First control circuit 106 supplies the gate of the first transistor TA with the cut-off voltage after amplifying circuit 102A substantially holds the amplified signal.

Next, the operation of semiconductor device 200 will be described.

While the signal level of control signal VREFOFF is the “L” level, control circuit 106 outputs input voltage Vim to the gate of transistor TA.

While the signal level of control signal VREFOFF is the “L” level, if the signal levels of control signals PREB1 and PREB2 become the “H” level, the signal level of sense start signal SENT1 becomes the “H” level, and the signal level of amplifier activation signal SENT2 becomes the “H” level, voltage comparing circuit 101 compares input voltage Vim and input voltage Vip and outputs the compared result to terminal A and terminal B. Thereafter, amplifying circuit 102A amplifies the compared result and holds the amplified compared result.

Thereafter, when the signal level of sense start signal SENT1 becomes the “L” level and the signal level of control signal VREFOFF becomes the “H” level, transistor L1 is turned off and control circuit 106 turns off transistor TA so as to cause voltage comparing circuit 101 to deactivate the comparison operation and shut off the path of a current that flows in amplifying circuit 102A through transistor TA and transistor TB in succession.

Next, the effect of this embodiment will be described.

According to this embodiment, after amplifying circuit 102A substantially holds the compared result of input voltages Vim and Vip, control circuit 106 turns off transistor TA so as to shut off the path of a current that flow in amplifying circuit 102A through transistors TA and TB in succession.

Thus, current can be prevented from flowing in amplifying circuit 102A through transistors TA and TB in succession.

Thus, the current consumption of differential amplifying circuit 1A (200) can be reduced.

### Second Embodiment

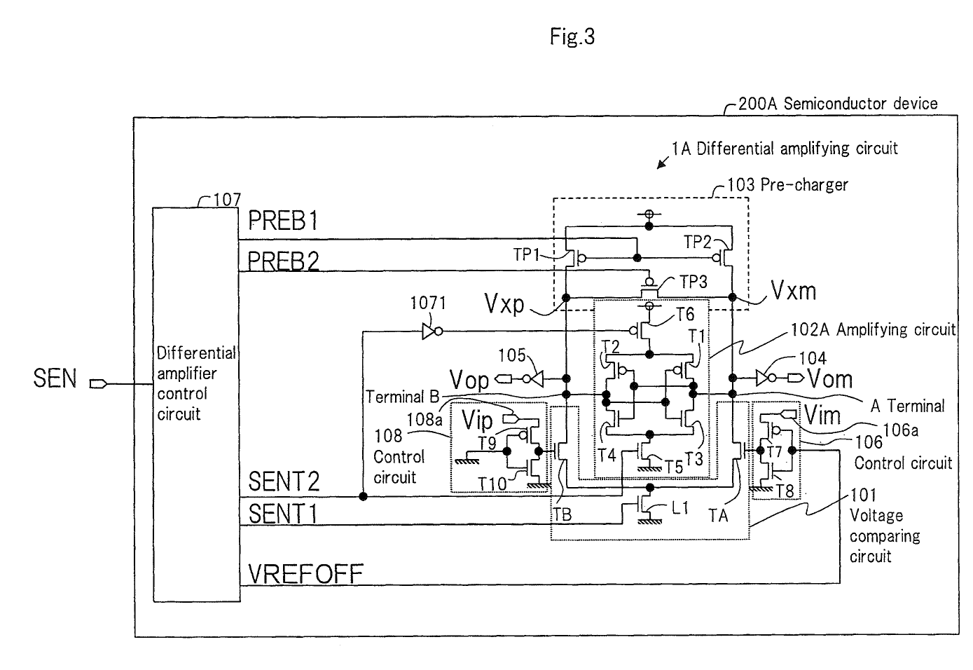

FIG. 3 is a schematic diagram showing semiconductor device 200A according to a second embodiment of the present invention. In FIG. 3, similar structures to those in FIG. 2 are denoted by similar reference numerals and their description will be omitted.

Semiconductor device 200A according to the second embodiment is different from semiconductor device 200 according to the first embodiment in that the former also includes control circuit 108 that uses input voltage Vip as a power supply voltage and that is connected to transistor TB so as to equally balance the resistors of transistors TA and TB.

Next, semiconductor device 200A according to the second embodiment will be described focused on the differences between it and differential semiconductor device 200 according to the first embodiment.

In FIG. 3, control circuit 108 uses input voltage Vip as a power supply voltage and is connected to the gate of transistor TB. Control circuit 108 is an example of a second control circuit and a second inverter circuit.

Control circuit 108 includes input terminal 108a for input voltage Vip, PMOS transistor T9, and NMOS transistor T10.

The source of transistor T9 is connected to input terminal 108a; and the drain of transistor T9 is connected to the gate of transistor TB. The source of transistor T10 is connected to the ground; and the drain of transistor T10 is connected to the gate of transistor TB. The gate of each of transistors T9 and T10 is connected to the ground. The ground is an example of a power voltage. The source of transistor T9 is an example of a power node of the second inverter circuit. A combination of the drain of transistor T9 and the drain of transistor T10 is an example of an output node of the second inverter circuit. A combination of the gate of the transistor T9 and the gate of transistor T10 is an example of an input node of the second inverter circuit.

According to this embodiment, a control circuit, which includes control circuits 106 and 108, supplies a gate of the second transistor TB with the second input voltage Vip after amplifying circuit 102A substantially holds the amplified signal.

Second control circuit 108 is configured to supply the gate of the second transistor TB with the second input voltage Vip.

The power node of the second inverter circuit 108 is supplied with the second input voltage Vip. The input node of the second inverter circuit 108 is supplied with the power voltage. The output node of the second inverter circuit 108 is coupled to the gate of the second transistor TB.

Second control circuit 108 supplies the gate of the second transistor TB with the cut-off voltage after amplifying circuit 102A substantially holds the amplified signal.

According to this embodiment, since control circuit 106 is connected to the gate of transistor TA and control circuit 108 is connected to the gate of transistor TB, resistances of transistors TA and TB can be equally balanced.

### Third Embodiment

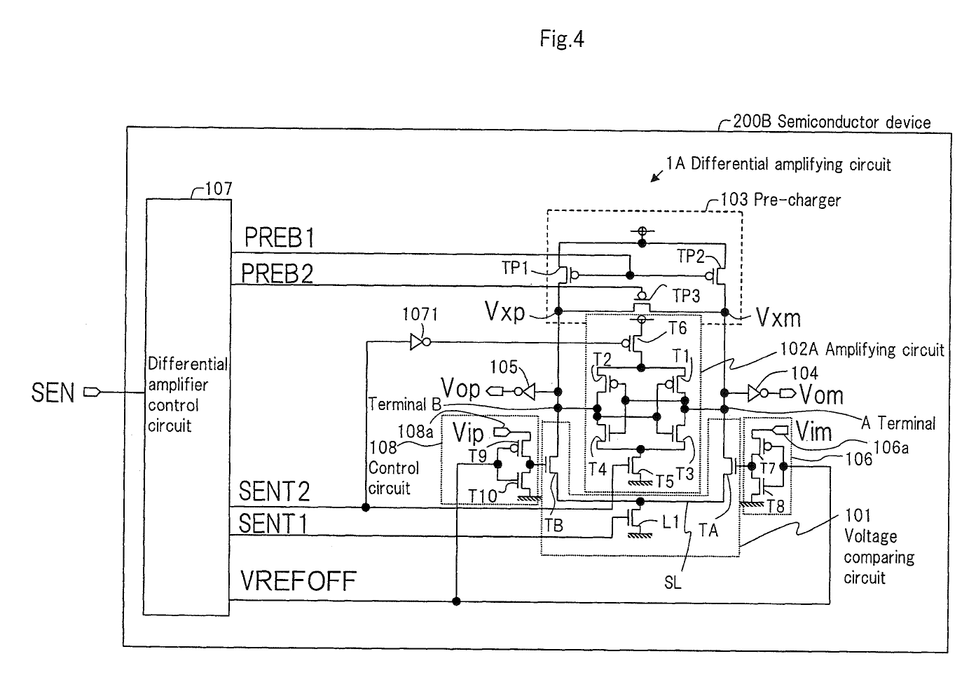

FIG. 4 is a schematic diagram showing semiconductor device 200B according to a third embodiment of the present invention. In FIG. 4, similar structures to those in FIG. 3 are denoted by similar reference numerals and their description will be omitted.

Semiconductor device 200B according to the third embodiment is different from semiconductor device 200A according to the first embodiment in that control circuit 108 is also controlled corresponding to control signal VREFOFF.

Next, semiconductor device 200B according to the third embodiment will be described focused on the differences with differential semiconductor device 200A according to the second embodiment.

In FIG. 4, control circuit 108 is an example of circuit means and a circuit. Control signal VREFOFF is input to the gate of each of transistors T9 and T10. Transistor T9 is an example of a fifth transistor; and transistor T10 is an example of a sixth transistor. The gate of transistor TB is an example of a control electrode of the second transistor.

After control circuit 108 substantially holds the compared result of voltage comparing circuit 101, control circuit 108 turns off transistor TB so as to shut off the path (route) of current that flows in amplifying circuit 102A through transistor TA and transistor TB that are connected in series.

As described above, semiconductor device 200B according to this embodiment has circuits 106 and 108 that supply a ground voltage that shuts off first transistor TA and second transistor TB thereto instead of first input voltage Vim and second input voltage Vip supplied thereto.

In semiconductor device 200B according to this embodiment, control circuit 106 includes third transistor T7 connected between input terminal 106a for first input voltage Vim and the control electrode of first transistor TA; and fourth transistor T8 connected between the control electrode of first transistor TA and a shut-off voltage supply line (ground). Control circuit 108 includes fifth transistor T9 connected between input terminal 108a for second input voltage Vip and the control electrode of second transistor TB; and sixth transistor T10 connected between the control electrode of second transistor TB and the supply line (ground). After amplifying circuit 102A substantially holds the compared result of first input voltage Vim and second input voltage Vip, third transistor T7 and fifth transistor T9 are caused to change from the conductive state to the shut-off state, whereas fourth transistor T8 and eighth transistor T10 are caused to change from the shut-off state to the conductive state.

According to this embodiment, the control circuit, which includes control circuits 106 and 108, supplies a gate of the second transistor TB with the cut-off voltage after amplifying circuit 102A substantially holds the amplified signal.

Second control circuit 108 is configured, when activated, to supply a gate of the second transistor TB with the cut-off voltage, when inactivated, to supply the gate of the second transistor TB with the second input voltage Vip.

The power node of the second inverter circuit 108 is supplied with the second input voltage Vip. The input node of the second inverter circuit 108 is supplied with control signal VREFOFF. The output node of the second inverter circuit 108 is coupled to the gate of the second transistor TB.

According to this embodiment, after amplifying circuit 102A substantially holds the compared result of the first and second input voltages, control circuits 106 and 108 turn off transistors TA and TB respectively so as to shut off the path of a current that flows in amplifying circuit 102A through control circuits 106 and 108 that are connected in series. Thus, current can be prevented from flowing in amplifying circuit 102A through transistors TA and TB in succession. As a result, the current consumption of differential amplifying circuit 1A (semiconductor device 200B) can be reduced.

### Fourth Embodiment

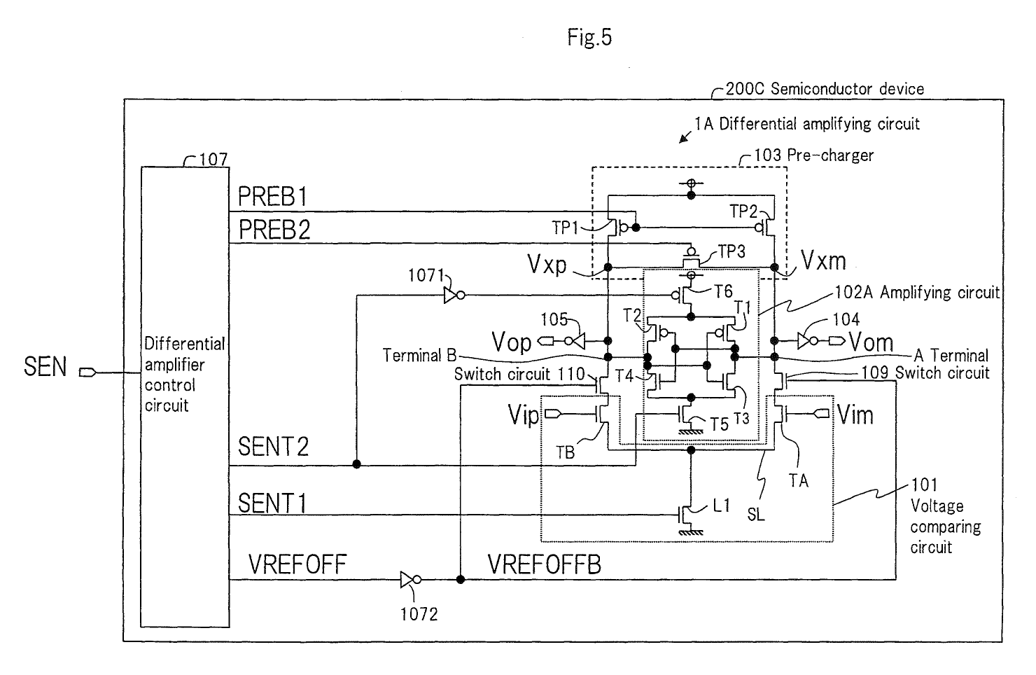

FIG. 5 is a schematic diagram showing semiconductor device 200C according to a fourth embodiment of the present invention. In FIG. 5, similar structures to those in FIG. 2 are denoted by similar reference numerals and their description will be omitted.

Semiconductor device 200C according to the fourth embodiment is different from semiconductor device 200 according to the first embodiment in that the former does not include control circuit 106, but includes switch circuit 109 located between amplifying circuit 102A and transistor TA and switch circuit 110 located between amplifying circuit 102A and transistor TB such that switch circuit 109 and 110 can shut off the path of a current that flows in amplifying circuit 102A.

Next, semiconductor device 200C according to the fourth embodiment will be described focused on the differences between it and differential semiconductor device 200 according to the first embodiment.

In FIG. 5, each of switch circuits 109 and 110 is composed of, for example, an NMOS transistor. Terminal A is an example of a first input; and terminal B is an example of a second input.

The source of transistor 109 is connected to the drain of transistor TA; and the drain of transistor 109 is connected to terminal A. The source of transistor 110 is connected to the drain of transistor TB; and the drain of transistor 110 is connected to terminal B. Supplied to the gate of transistor 109 and the gate of transistor 110 is control signal VREFOFFB in which control signal VREFOFF is inverted by inverter I072.

Thus, semiconductor device 200C according to this embodiment includes switch circuit 109 located between first transistor TA and amplifying circuit 102A. After amplifying circuit 102A substantially holds the compared result of first input voltage Vim and second input voltage Vip, switch circuit 109 is turned off.

Switch circuit 109 or 110 is inserted in series with at least one of the first and second transistors TA and TB and is configured, when turned OFF, to cut off a current flowing into the at least one of the first and second transistors TA and TB.

In addition, according to this embodiment, amplifying circuit 102A has first input A and second input B electrically connected to the output side of first transistor TA and the output side of second transistor TB, respectively. Semiconductor device 200C includes first switch circuit 109 located between first transistor TA and first input A of amplifying circuit 102A and second switch circuit 110 located between second transistor TB and second input B of amplifying circuit 102A. After amplifying circuit 102A substantially holds the compared result of first input voltage Vim and second input voltage Vip, first switch circuit 109 and second switch circuit 110 are turned off.

In addition, according to this embodiment, each of first switch circuit 109 and second switch circuit 110 are each composed of a transistor.

According to this embodiment, After amplifying circuit 102A substantially holds the compared result of first and second input voltages, since switch circuits 109 and 110 turn off transistors TA and TB, the path of current that flows in amplifying circuit 102A through transistors TA and TB in succession is shut off. Consequently, current that flows in amplifying circuit 102A through transistors TA and TP that are connected in series can be prevented. As a result, the current consumption of differential amplifying circuit 1A (semiconductor device 200C) can be reduced.

According to this embodiment, switch circuit 109 or 110 may be omitted.

Next, examples of differential amplifier control circuit 107 shown in FIG. 2 to FIG. 5 will be described.

### First Example of Differential Amplifier Control Circuit 107″

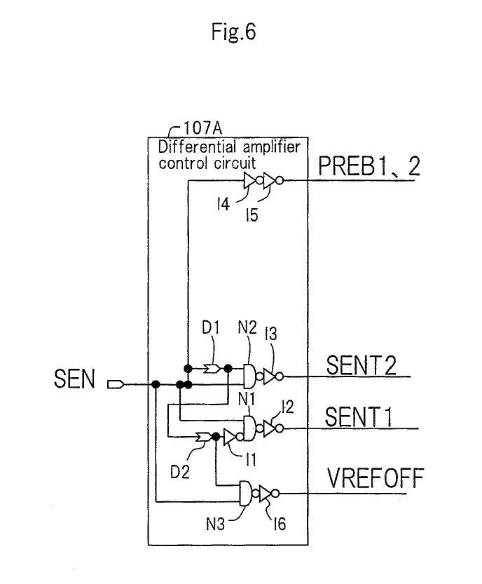

FIG. 6 is a schematic diagram showing differential amplifier control circuit 107A according to a first example of differential amplifier control circuit 107.

In FIG. 6, differential amplifier control circuit 107A includes delay circuits D1 and D2, NAND gates N1 to N3, and inverters I1 to I6.

Delay circuit D1 delays sense start signal SEN for a first period. Delay circuit D2 delays the output of delay circuit D1 for a second period. Inverter I1 inverts the output of delay circuit D1. NAND gate N1 accepts sense start signal SEN and the output of inverter I1. Inverter I2 inverts the output of NAND gate N1 and outputs sense start signal SENT1.

NAND gate N2 accepts sense start signal SEN and the output of delay circuit D1. Inverter I3 inverts the output of NAND gate N2 and outputs amplifier activation signal SENT2.

Inverter I4 inverts sense start signal SEN, Inverter I5 inverts the output of inverter I4. The output of inverter I5 is used as control signals PREB1 and PREB2.

NAND gate N3 accepts sense start signal SEN and the output of delay circuit D2. Inverter I6 inverts the output of NAND gate N3 and outputs control signal VREFOFF.

In the following, it is assumed that the delay periods of NAND gates N1 to N3 and inverters I1 to I6 are identical and denoted by “TD.”

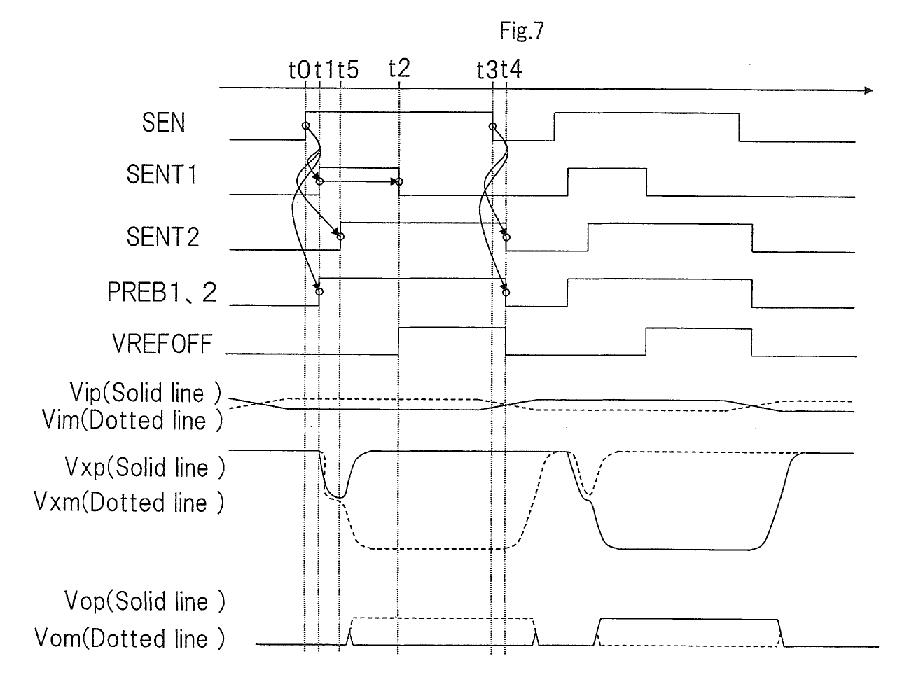

FIG. 7 is an operation waveform diagram describing the operation of differential amplifier control circuit 107A that is used as differential amplifier control circuit 107.

In FIG. 7, the period of timing t0 to t1 is “TD+TD=2TD,” the period of timing t1 to t5 is “first period” of delay circuit D1, the period of timing t5 to t2 is “second period” of delay circuit D2, and the period of timing t3 to t4 is “2TD.”

In FIG. 7, when the signal level of sense start signal SEN becomes the “H” level at timing t0, the signal levels of sense start signal SENT1 and control signals PREB1 and PREB2 become the “H” level at timing t1.

When the signal levels of sense start signal SENT1 and control signals PREB1 and PREB2 become the “H” level, pre-charger 103 stops pre-charging and transistor L1 is turned on.

Thus, voltage comparing circuit 101 compares input voltage Vim and input voltage Vip and outputs the compared result to terminals A and B. In FIG. 7, the voltage at terminal A is represented by Vxm (dotted line), whereas the voltage at terminal B is represented by Vxp (solid line).

Thereafter, when the signal level of amplifier activation signal SENT2 becomes the “H” level at timing t5, amplifying circuit 102A amplifies the difference between voltage Vxm at terminal A and voltage Vxp at terminal B (compared result) and holds (latches) the amplified compared result.

Thereafter, when the signal level of sense start signal SENT1 becomes the “L” level and the signal level of control signal VREFOFF becomes the “H” level at timing t2, transistor L1 is turned off and both transistors TA and TB or only transistor TA is turned off and thereby the path (route) of current that flows in amplifying circuit 102A through transistor TA and transistor TB in succession is shut off.

Thereafter, when the signal level of sense start signal SEN becomes the “L” level at timing t3, the signal levels of amplifier activation signal SENT2 and control signals PREB1, PREB2, and VREFOFF becomes the “L” level at timing t4 and thereby they return to the initial state.

According to this example, the amplifying circuit starts to amplify the output voltage of the voltage comparing circuit after the voltage comparing circuit starts to compare the first and second input voltages Vim and Vip.

According to this example, since the period after the voltage comparing circuit is activated (the signal level of sense start signal SENT1 becomes the “H” level) until the amplifying circuit is activated (the signal level of amplifier activation signal SENT2 becomes the “H” level) is sufficiently long, even if stray capacitances of the node pair under amplification (terminals A and B) are unbalanced, the differential amplifying circuit can stably amplify differential signals with reduced likelihood of occurrence of incorrect differential signals.

In addition, when the differential amplifier control circuit according to this example is used, amplifying circuit 102 of differential amplifying circuit 1A may directly supply a power supply voltage to PMOS transistors T1 and T2 not through transistor T6. In this structure, when the voltage comparing circuit starts comparing voltages, since PMOS transistors T1 and T2 of the amplifying circuit function as a PMOS latch circuit, they help the comparing operation of the voltage comparing circuit. However, in this structure, it is necessary that the period after the voltage comparing circuit is activated (the signal level of sense start signal SENT1 becomes the “H” level) until the amplifying circuit is activated (the signal level of amplifier activation signal SENT2 becomes the “H” level) be sufficiently long. Thus, after DC currents that flow in the load of the PMOS latch circuit and the NMOS voltage comparing circuit are balanced and next, after a desired potential is obtained from the resistance ratio, amplifier activation signal SENT2 needs to be activated.

Differential amplifier control circuit 107A shown in FIG. 6 can be applied to differential amplifier control circuit 107 of semiconductor device 200 shown in FIG. 2 to FIG. 5.

### Second Example of Differential Amplifier Control Circuit 107

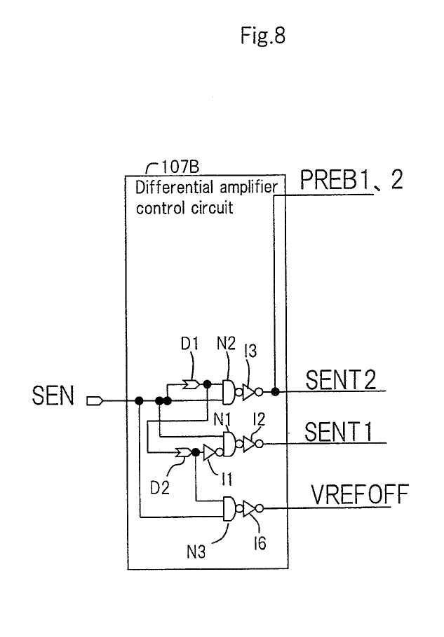

FIG. 8 is a schematic diagram showing differential amplifier control circuit 107B according to a second example of differential amplifier control circuit 107. In FIG. 8, similar structures to those in FIG. 6 are denoted by similar reference numerals and their description will be omitted.

Differential amplifier control circuit 107B according to the second example is different from differential amplifier control circuit 107A according to the first example in that the former does not include inverts I4 and I5 and uses amplifier activation signal SENT2 as control signals PREB1 and PREB2.

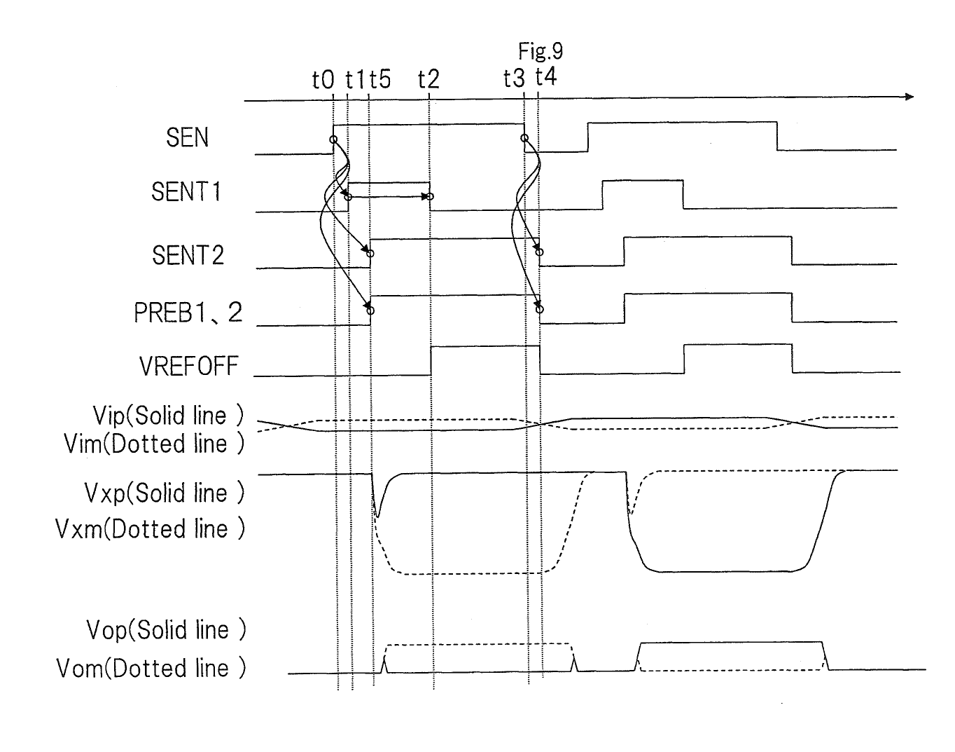

FIG. 9 is an operation waveform diagram describing the operation of differential amplifier control circuit 107B that is used as differential amplifier control circuit 107.

In FIG. 9, the periods of timings are the same as those shown in FIG. 7.

In FIG. 9, when the signal level of sense start signal SEN becomes the “H” level at timing t0, the signal level of sense start signal SENT1 becomes the “H” level at timing t1. When the signal level of sense start signal SENT1 becomes the “H” level, transistor L1 is turned on. Thereafter, when the signal levels of amplifier activation signal SENT2 and control signals PREB1 and PREB2 become the “H” level at timing t5, voltage comparing circuit 101 outputs the compared result of input voltages Vim and Vip to terminals A and B, respectively, amplifying circuit 102A amplifies the difference of voltage Vxm at terminal A and voltage Vxp at terminal B (compared result) and holds (latches) the amplified compared result.

Thereafter, when the signal level of sense start signal SENT1 becomes the “L” level and the signal level of control signal VREFOFF becomes the “H” level at timing t2, transistor L1 is turned off and both transistors TA and TB are turned off, or only transistor TA is turned off. As a result, the path (route) of current that flows in amplifying circuit 102A through transistors TA and TB in succession is shut off.

Thereafter, when the signal level of sense start signal SEN becomes the “L” level at timing t3, the signal levels of amplifier activation signal SENT2 and control signals PREB1, PREB2, and VREFOFF become the “L” level at timing t4 and thereby they return to the initial state.

According to this example, since the period after the voltage comparing circuit is activated (the signal level of sense start signal SENT1 becomes the “H” level) until the amplifying circuit is activated (the signal level of amplifier activation signal SENT2 becomes the “H” level) is sufficiently long, even if stray capacitances of the node pair under amplification (terminals A and B) are unbalanced, DC current that flows in the load of PMOS resistance of the pre-charger and the NMOS voltage comparing circuit is balanced. In addition, even if a PMOS latch load occurs in the PMOS transistor of the amplifying circuit, if the resistance ratio is adjusted such that they are balanced out of the latch operation point, the likelihood of incorrect amplification due to the PMOS latch load can be reduced and thereby a desired potential can be more stably obtained. The load of the PMOS resistance that is composed of the pre-charger may be formed by only TP1 and TP2, not TP3 that is turned off. This example allows the differential amplifier to have an increased gain. In addition, since the amplifying circuit is activated (the signal level of amplifier activation signal SENT2 becomes the “H” level) and next, since the voltage comparing circuit is deactivated (the signal level of sense start signal SENT1 becomes “L” level), the differential amplifying circuit can stably amplify differential voltages with reduced likelihood of incorrect amplification. Differential amplifier control circuit 107B shown in FIG. 8 can be applied to differential amplifier control circuit 107 in semiconductor device 200 shown in FIG. 2 to FIG. 5.

### Third Example of Differential Amplifier Control Circuit 107

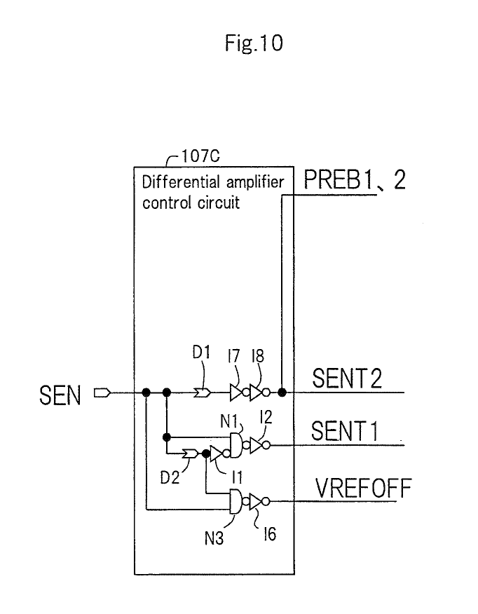

FIG. 10 is a schematic diagram showing differential amplifier control circuit 107C according to a third example of differential amplifier control circuit 107. In FIG. 10, similar structures to those in FIG. 6 are denoted by similar reference numerals and their description will be omitted.

Differential amplifier control circuit 107C according to the third example is different from differential amplifier control circuit 107A according to the first example in that the former does not include NAND gate N2 and inverters I3, I4, and I5, but includes inverters I7 and I8.

Next, differential amplifier control circuit 107C according to the third example will be described focused on the differences between it and differential amplifier control circuit 107A according to the first example.

Inverter I7 inverts the output of delay circuit D1. Inverter I8 inverts the output of inverter I7. The output of inverter I8 is used as amplifier activation signal SENT2 and control signals PREB1 and PREB2. Inverters I7 and I8 each has a delay period of “TD.”

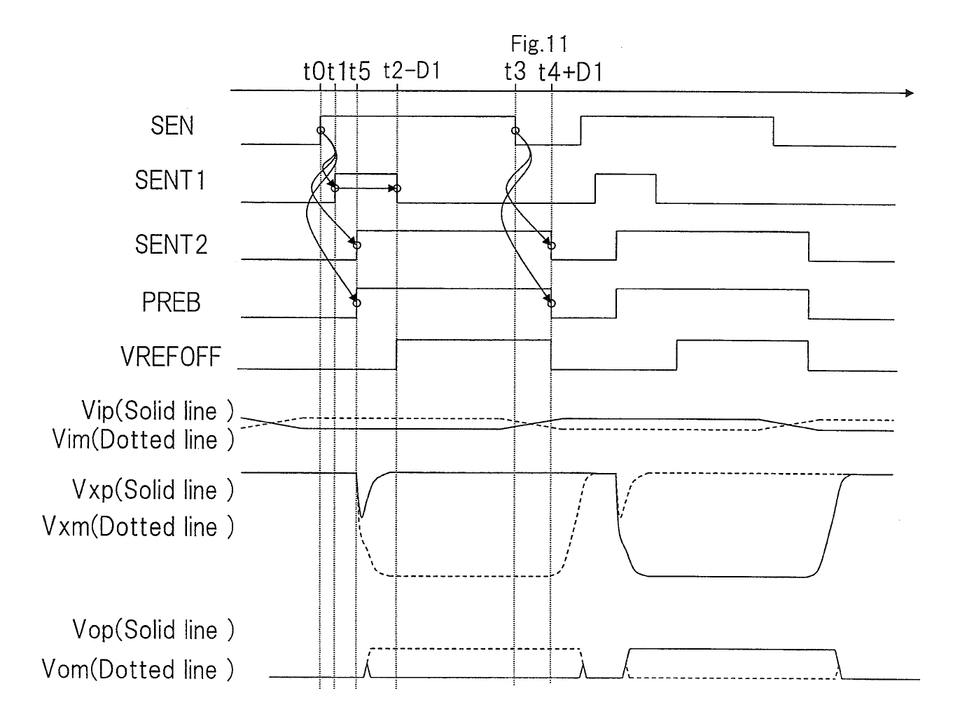

FIG. 11 is an operation waveform diagram describing the operation of differential amplifier control circuit 107C that is used as differential amplifier control circuit 107.

The operation waveform diagram shown in FIG. 11 is different from that shown in FIG. 9 in that the sense period of sense start signal SENT1 of the former is shorter than that of the latter by D1 and that the pre-charge start time of control signal PREB of the former delays by D1 compared with that of the latter. With respect to the first difference, if there is a sense margin, differential amplifier control circuit 107C normally operates. With respect to the second difference, if there is a margin after the pre-charging is completed until the next sense is started, differential amplifier control circuit 107C operates normally. The advantage of this example is that differential amplifier control circuit 107C can be more simply manufactured than the others and circuit corrections can be made at low cost.

Differential amplifier control circuit 107C shown in FIG. 10 can be applied to differential amplifier control circuit 107 of semiconductor device 200 shown in FIG. 2 to FIG. 5.

### Fourth Example of Differential Amplifier Control Circuit 107

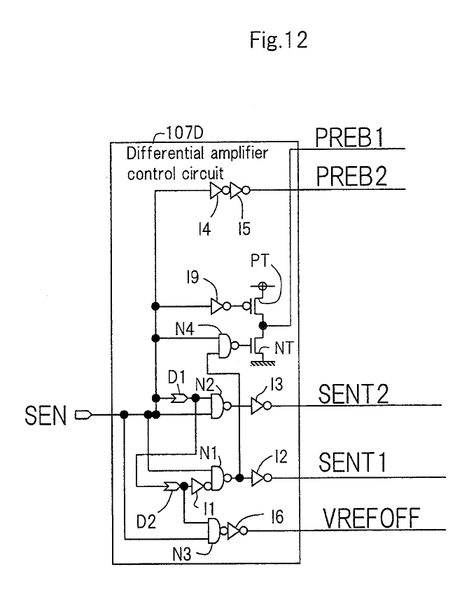

FIG. 12 is a schematic diagram showing differential amplifier control circuit 107D according to a fourth example of differential amplifier control circuit 107. In FIG. 12, similar structures to those in FIG. 6 are denoted by similar reference numerals and their description will be omitted.

Differential amplifier control circuit 107D according to the fourth example is different from differential amplifier control circuit 107A according to the first example in that former includes inverter I9, NAND gate N4, PMOS transistor PT, and NMOS transistor and that inverter I9, NAND gate N4, PMOS transistor PT, and NMOS transistor NT generate control signal PREB1.

Next, differential amplifier control circuit 107D according to the fourth example will be described focused on the differences between it and differential amplifier control circuit 107A according to the first example.

Inverter I9 inverts sense start signal SEN. NAND gate N4 accepts sense start signal SEN and the output of NAND gate N1. The source of transistor PT is connected to power supply VDD (current source); the drain of transistor PT is connected to the drain of transistor NT; and the gate of transistor PT accepts the output of inverter I9. The source of transistor NT is connected to the ground; the drain of transistor NT is connected the drain of transistor PT; and the gate of transistor NT accepts the output of NAND gate N4. The outputs of the drains of transistors PT and NT are used as control signal PREB1. The output of inverter I5 is used as control signal PREB2. Transistors PT and NT each have a delay period of “TD.”

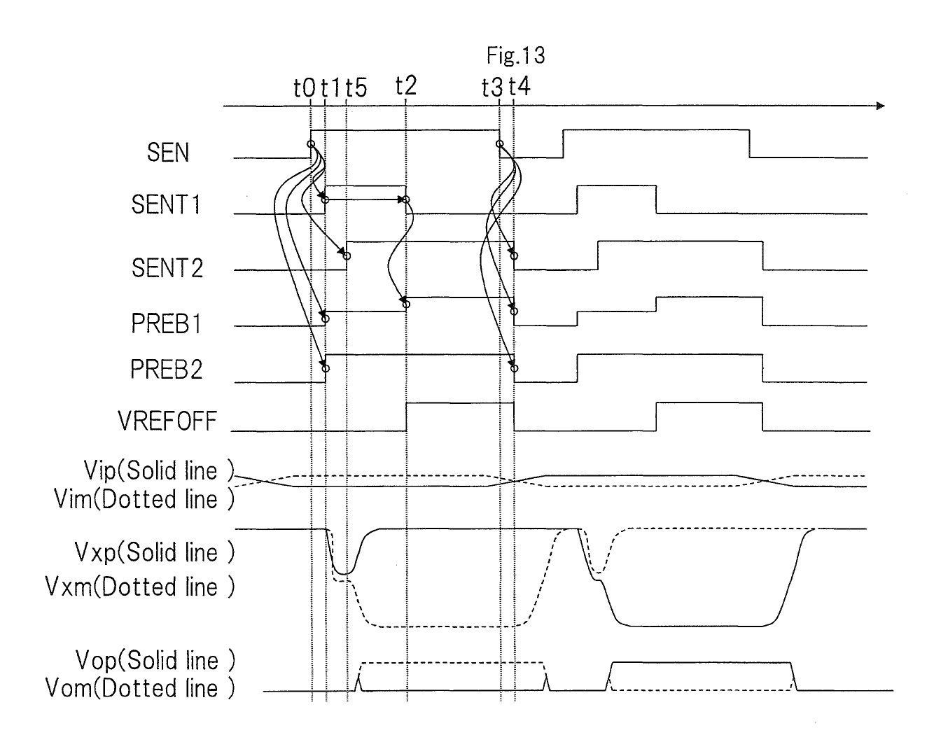

FIG. 13 is an operation waveform diagram describing the operation of differential amplifier control circuit 107D that is used as differential amplifier control circuit 107.

In FIG. 13, the periods of timings are the same as those shown in FIG. 7.

In FIG. 13, when the signal level of sense start signal SEN becomes the “H” level at timing t0, the signal levels of sense start signal SENT1 and control signal PREB2 become the “H” level at timing t1. Thus, transistor TP3 is turned off and transistor L1 is turned on. Thereafter, voltage comparing circuit 101 compares input voltage Vim and input voltage Vip and outputs the compared result to terminals A and B.

Thereafter, transistors PT and NT (see FIG. 12) are turned on at timing t1. The on-resistances of transistors PT and NT form a voltage dividing circuit. As a result, the signal level of control signal PREB1 becomes the intermediate level.

At this point, transistors TA and TB of voltage comparing circuit 101 form a CMOS differential amplifier having loads of transistors TP1 and TP2. If the voltage levels of the gates of PMOS transistors TP1 and TP2 are adjusted, since the CMOS differential amplifier can be operated in the saturation region, it can be expected to obtain a large amplification factor. According to this example, the signal level of control signal PREB1 is caused to become the intermediate level so as to increase the amplification factor. Moreover, in amplifying circuit 102A, transistor T6 is turned off such that it does not adversely affect the operation of the CMOS differential amplifier.

If this state is satisfactorily kept, even if stray capacitances of terminals A and B are unbalanced, DC currents that flow in PMOS transistors TP1 and TP2 and NMOS transistors TA and TB are balanced and thereby the potential between input voltage Vim and input voltage Vip obtained from their resistance ratio can be amplified with a high amplifying effect.

Thereafter, when the signal level of amplifier activation signal SENT2 becomes the “H” level at timing t5, amplifying circuit 102A amplifies the difference between voltage Vxm at terminal A and voltage Vxp at terminal B (compared result) and holds (latches) the amplified compared result.

Thereafter, when the signal level of sense start signal SENT1 becomes the “L” level and the signal level of control signal VREFOFF becomes the “H” level at timing t2, transistors L1, TP1, and TP2 are turned off and both transistors TA and TB are turned off, or only transistor TA is turned off and thereby the path (route) of current that flows in amplifying circuit 102A through transistor TA and transistor TB in succession is shut off.

Thereafter, when the signal level of sense start signal SEN becomes the “L” level at timing t3, the signal levels of amplifier activation signal SENT2 and control signals PREB1, PREB2, and VREFOFF become the “L” level at timing t4 and thereby they return to the initial state.

According to this embodiment, since the period after the voltage comparing circuit is activated (the signal level of sense start signal SENT1 becomes the “H” level) until the amplifying circuit is activated (the signal level of amplifier activation signal SENT2 becomes the “H” level) is sufficiently long, even if stray capacitances of the node pair under amplification (terminals A and B) are unbalanced and the CMOS differential amplifier has a high gain, it can stably obtain the desired potential. In addition, since the amplifying circuit is activated (the signal level of amplifier activation signal SENT2 becomes the “H” level) and then the voltage comparing circuit is inactivated (the signal level of sense start signal SENT1 becomes the “L” level), the differential amplifying circuit can stably amplify differential signals with reduced likelihood of occurrence of incorrect differential signals.

Differential amplifier control circuit 107D shown in FIG. 12 can be applied to differential amplifier control circuit 107 of semiconductor device 200 shown in FIG. 2 to FIG. 5.

In the differential amplifier control circuits according to the first to fourth examples, especially in semiconductor devices 200B and 200C shown in FIGS. 4 and 5, respectively, when the signal level of control signal VREFOFF becomes the “H” level, since the signal level of sense start signal SENT1 falls to the “L” level, the source line SL portion of transistors TA and TB of differential amplifying circuit 1A enters a floating state.

Next, an example of differential amplifier control circuit 107 of semiconductor devices 200B and 200C shown in FIG. 4 and FIG. 5, respectively, will be described in which after the signal level of control signal VREFOFF becomes the “H” level, namely transistors TA and TB are turned off, the signal level of sense start signal SENT1 is caused to become the “H” level and thereby transistor L1 keeps on being turned on. However, like the examples of differential amplifier control circuit 107 that follow, even if the signal level of sense start signal SENT1 is kept in the “H” level, since transistors TA and TB of differential amplifying circuit 1A of semiconductor devices 200B and 200C shown in FIG. 4 and FIG. 5 are turned off, after source line SL becomes VSS, current that flows in transistor L1 does not increase. Thus, even if the signal level of sense start signal SENT1 is kept in the “H” level in the examples that follow, the current consumption hardly increases.

### Fifth Example of Differential Amplifier Control Circuit 107

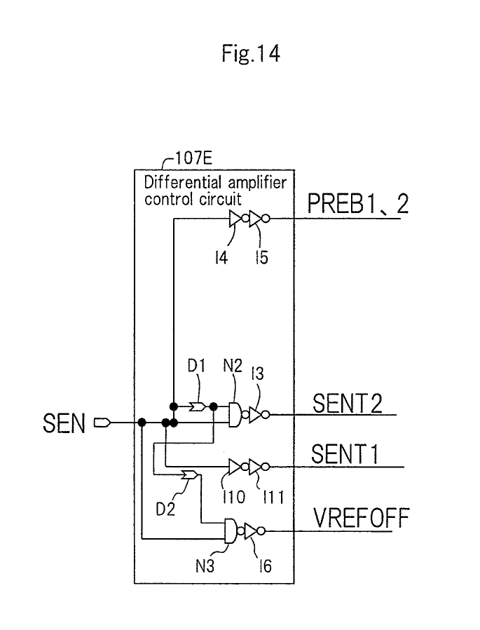

FIG. 14 is a schematic diagram showing differential amplifier control circuit 107E according to a fifth example of differential amplifier control circuit 107. In FIG. 14, similar structures to those in FIG. 6 are denoted by similar reference numerals and their description will be omitted.

Differential amplifier control circuit 107E according to the fifth example is different from differential amplifier control circuit 107A according to the first example in that the former includes inverters I10 and I11, but does not include inverters I1 and I2 and NAND gate N1.

Next, differential amplifier control circuit 107E according to the fifth example will be described focused on the differences with differential amplifier control circuit 107A according to the first example.

Inverter I10 inverts sense start signal SEN. Inverter I11 inverts the output of inverter I10 and outputs sense start signal SENT1. Inverters I10 and I11 each have a delay period of “TD.”

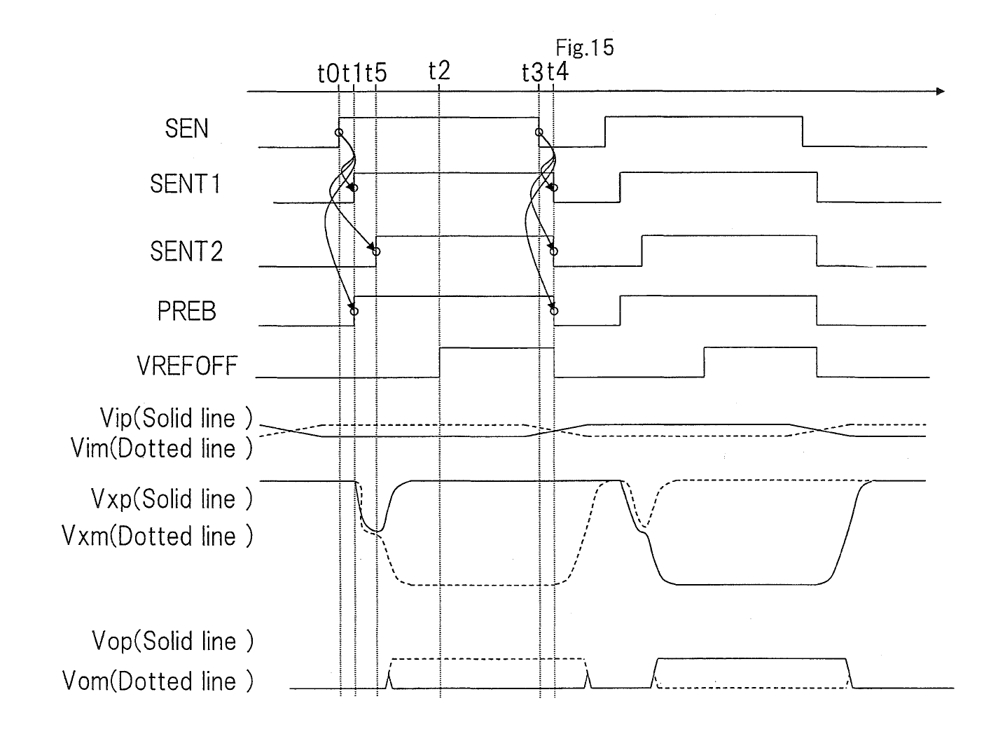

FIG. 15 is an operation waveform diagram describing the operation of differential amplifier control circuit 107E that is used as differential amplifier control circuit 107.

In FIG. 15, the periods of timings are the same as those shown in FIG. 7. As shown in FIG. 15, when the signal level of control signal VREFOFF becomes the “H” level, sense start signal SENT1 is kept in the “H” level.

Differential amplifier control circuit 107E shown in FIG. 14 is preferably applied to differential amplifier control circuit 107 of semiconductor devices 200B and 2000 shown in FIG. 4 and FIG. 5, respectively.

### Sixth Example of Differential Amplifier Control Circuit 107

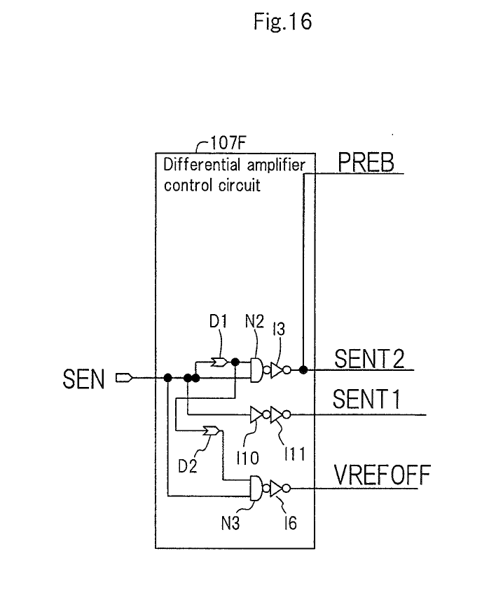

FIG. 16 is a schematic diagram showing differential amplifier control circuit 107F according to a sixth example of differential amplifier control circuit 107. In FIG. 16, similar structures to those in FIG. 8 and FIG. 14 are denoted by similar reference numerals and their description will be omitted.

Differential amplifier control circuit 107F according to the sixth example is different from differential amplifier control circuit 107B according to the second example in that the former includes inverters I10 and I11, but does not include inverters I1 and I2 and NAND gate N1.

When the signal level of control signal VREFOFF becomes the “H” level, differential amplifier control circuit 107F according to the sixth example causes the signal level of sense start signal SENT1 to be kept in the “H” level.

### Seventh Example of Differential Amplifier Control Circuit 107

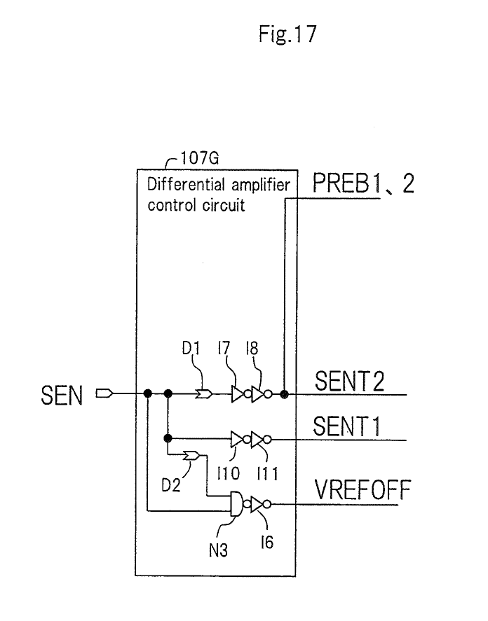

FIG. 17 is a schematic diagram showing differential amplifier control circuit 107G according to a seventh example of differential amplifier control circuit 107. In FIG. 17, similar structures to those in FIG. 10 and FIG. 14 are denoted by similar reference numerals and their description will be omitted.

Differential amplifier control circuit 107G according to the seventh example is different from differential amplifier control circuit 107C according to the third example in that the former includes inverters I10 and I11, but does not include inverters I1 and I2 and NAND gate N1.

When the signal level of control signal VREFOFF becomes the “H” level, differential amplifier control circuit 107G according to the seventh example causes the signal level of sense start signal SENT1 to be kept in the “H” level. Eighth example of differential amplifier control circuit 107

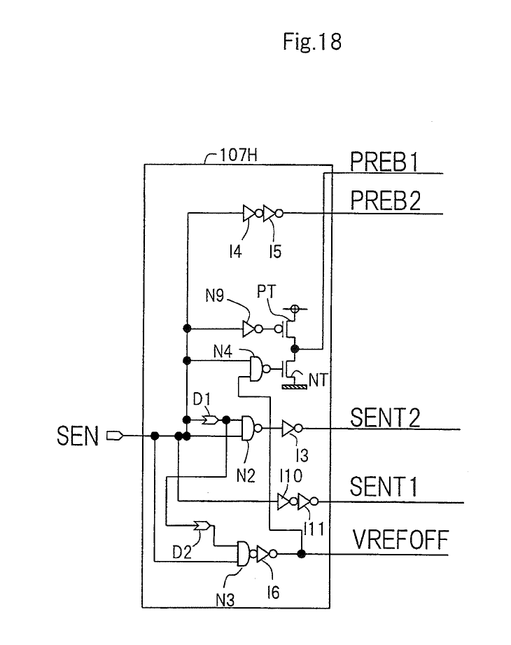

FIG. 18 is a schematic diagram showing differential amplifier control circuit 107H according to an eighth example of differential amplifier control circuit 107. In FIG. 18, similar structures to those in FIG. 12 and FIG. 14 are denoted by similar reference numerals and their description will be omitted.

Differential amplifier control circuit 107H according to the eighth example is different from differential amplifier control circuit 107D according to the fourth example in that the former includes inverters I10 and I11, but does not include inverters I1 and I2 and NAND gate N1 and in that NAND gate N4 accepts the output of inverter I6 instead of the output of NAND gate N1.

When the signal level of control signal VREFOFF becomes the “H” level, differential amplifier control circuit 107H according to the eighth example causes the signal level of sense start signal SENT1 to be kept in the “H” level.

### Ninth Example of Differential Amplifier Control Circuit 107

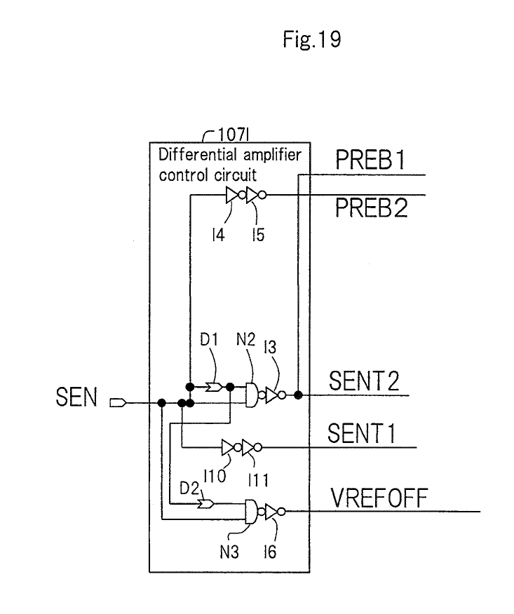

FIG. 19 is a schematic diagram showing differential amplifier control circuit 107I according to a ninth example of differential amplifier control circuit 107. In FIG. 19, similar structures to those in FIG. 18 are denoted by similar reference numerals and their description will be omitted.

Differential amplifier control circuit 107I according to the ninth example is different from differential amplifier control circuit 107H according to the eighth example in which the former does not include inverter I9, NAND gate N4, and transistors PT and NT and in that the output of inverter I3 is used in common as amplifier activation signal SENT2 and control signal PREB1.

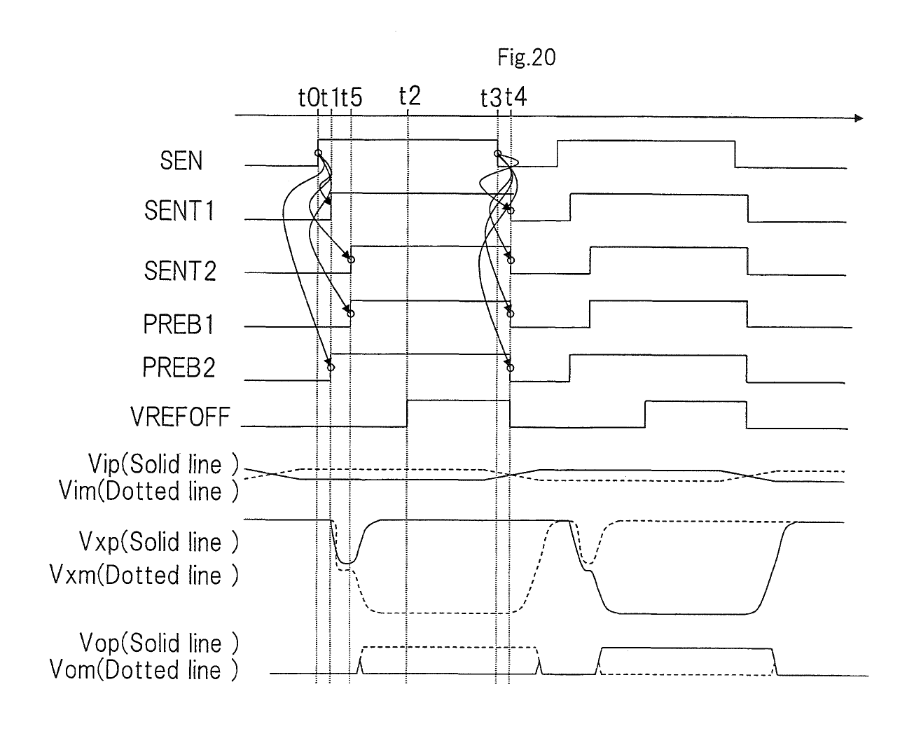

FIG. 20 is an operation waveform diagram describing the operation of differential amplifier control circuit 107I that is used as differential amplifier control circuit 107.

In FIG. 20, the periods of timings are the same as those shown in FIG. 7.

As shown in FIG. 20, when the signal level of control signal VREFOFF becomes the “H” level, the signal level of sense start signal SENT1 is kept in the “H” level.

Differential amplifier control circuits 107F to 107L shown in FIG. 16 to FIG. 19 are preferably applied to differential amplifier control circuit 107 of semiconductor devices 200B and 200C shown in FIG. 4 and FIG. 5.

### Example of Semiconductor Device

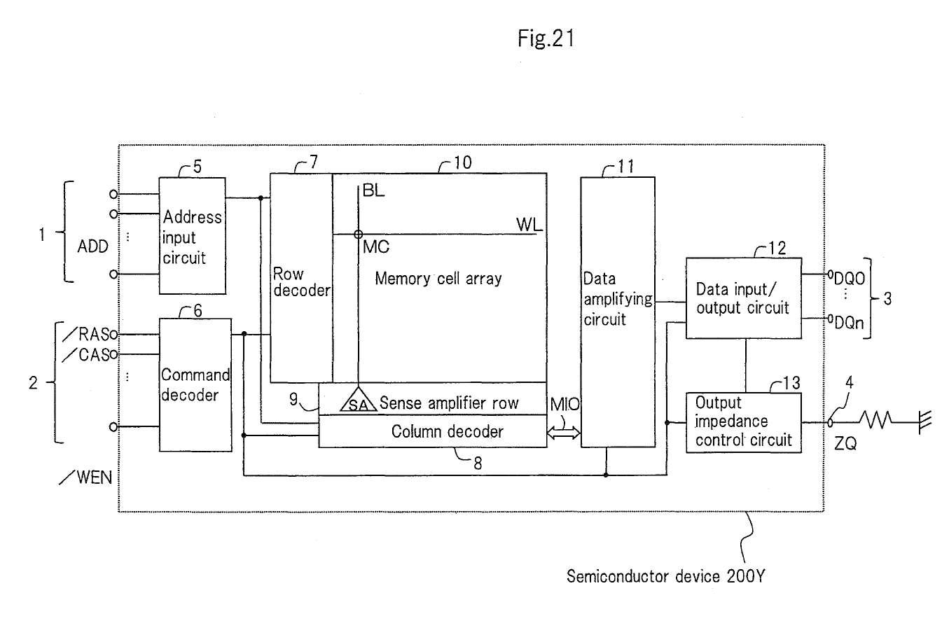

FIG. 21 is a schematic diagram showing an example of semiconductor device 200Y that uses a differential amplifying circuit according to each embodiment.

Semiconductor device 200Y is provided with external terminals that are address terminal block 1, command terminal block 2, data input/output terminal block 3, and calibration terminal 4.

In addition, semiconductor device 200Y includes address input circuit 5, command decoder 6, row decoder 7, column decoder 8, sense amplifier row 9, memory cell array 10, data amplifying circuit 11, data input/output circuit 12, output impedance control circuit 13, and main I/O line MIO.

Address input circuit 5 accepts an address signal from address terminal block 1, supplies a row address corresponding to the address signal to row decoder 7, and supplies a column address corresponding to the address signal to column decoder 8.

Command decoder 6 accepts a command signal from command terminal block 2 and generates an internal command signal corresponding to the command signal. Command decoder 6 outputs the internal command signal to row decoder 7, column decoder 8, data amplifying circuit 11, data input/output circuit 12, and output impedance control circuit 13.

Row decoder 7 selects any word line WL from memory cell array 10 corresponding to the row address and the internal command signal.

In memory cell array 10, a plurality of word lines WL and a plurality of bit lines BL intersect with each other and memory cells MC are located at the individual intersections (FIG. 21 shows only one word line WL, one bit line BL, and one memory cell MC). Bit line BL is connected to corresponding sense amplifier SA of sense amplifier row 9.

Column decoder 8 selects any sense amplifier SA from sense amplifier row 9 corresponding to the column address and the internal command signal. Sense amplifier SA selected by column decoder 8 is connected to data amplifying circuit 11 through main I/O line MIO.

When data are read from semiconductor device 200Y, data amplifying circuit 11 further amplifies read data amplified by sense amplifier SA and supplies the amplified read data to data input/output circuit 12. In contrast, when data are written to semiconductor device 200Y, data amplifying circuit 11 amplifies write data supplied from data input/output circuit 12 and supplies the amplified write data to sense amplifier SA.

Data input/output terminal block 3 is a terminal block that outputs read data DQ and inputs write data DQ and is connected to data input/output circuit 12.

Data input/output circuit 12 includes an output buffer. When data are read from semiconductor device 200Y, data input/output circuit 12 outputs read data DQ from the output buffer to data input/output terminal block 3. When data are written to semiconductor device 200Y, data input/output circuit 12 supplies write data DQ to data amplifying circuit 11.

When data are read from semiconductor device 200Y or it operates in an on-die-termination mode, output impedance control circuit 13 adjusts the impedance of the output buffer.

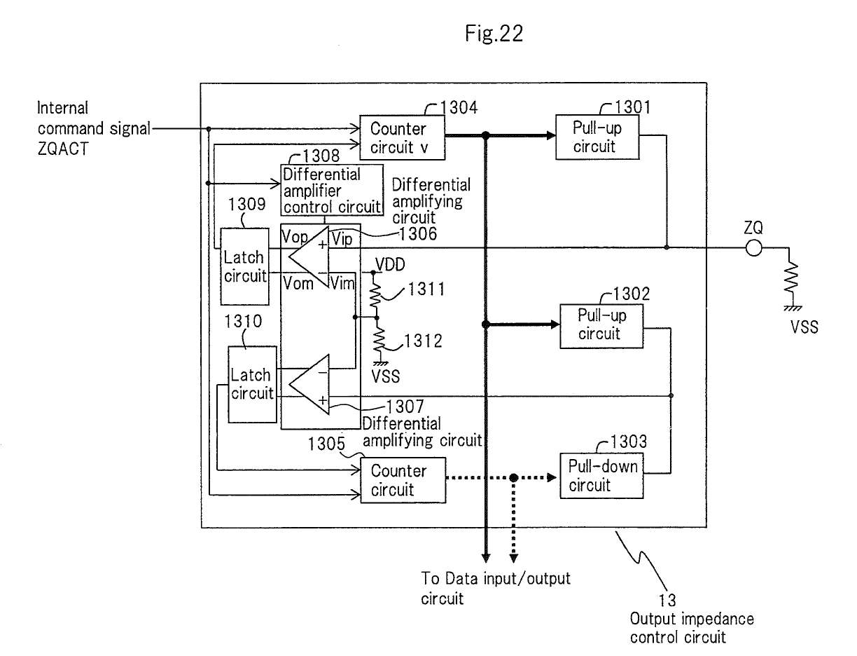

FIG. 22 is a schematic diagram showing output impedance control circuit 13.

Output impedance control circuit 13 includes pull-up circuits 1301 and 1302, pull-down circuit 1303, counter circuits 1304 and 1305, differential amplifying circuits 1306 and 1307, differential amplifier control circuit 1308, latch circuits 1309 and 1310, and resistors 1311 and 1312.

Differential amplifying circuit 1A shown in FIG. 2 to FIG. 5 is used for differential amplifying circuits 1306 and 1307. A differential amplifier control circuit according to any one of the first to ninth examples is used for differential amplifier control circuit 1308.

Internal command signal ZQACT is generated by command decoder 6 and is activated by external ZQ command that is input from the outside. Internal command signal ZQACT includes sense start signal SEN that is used as an enable signal for differential amplifying circuits 1306 and 1307.

Counter circuit 1304 is a counter that counts up or counts down when internal command signal ZQACT is activated. While the signal level of the output of latch circuit 1309 that latches the output of differential amplifying circuit 1306 is the “H” level, counter circuit 1304 counts up. While the signal level of the output of latch circuit 1309 is the “L” level, counter circuit 1304 counts down.

A non-inverted input terminal (+) of differential amplifying circuit 1306 is connected to calibration pin ZQ. An inverted input terminal (−) of differential amplifying circuit 1306 is connected to the connected point of resistors 1311 and 1312 that are respectively connected to power supply potential (VDD) and ground potential (GND).

Differential amplifying circuit 1306 compares the potential of calibration pin ZQ and the intermediate potential (VDD/2). If the former potential is higher than the latter potential, the signal level of the output of differential amplifying circuit 1306 becomes the “H” level. If the latter potential is higher than the former potential, the signal level of the output of differential amplifying circuit 1306 becomes the “L” level.

In contrast, counter circuit 1305 is a counter that counts up or counts down when internal command signal ZQACT is activated. While the signal level of the output of latch circuit 1310 that latches the output of differential amplifying circuit 1307 is the “H” level, counter circuit 1305 counts up. While the signal level of the output of latch circuit 1310 is the “L” level, counter circuit 1305 counts down.

A non-inverted input terminal (+) of differential amplifying circuit 1307 is connected to the connected point of pull-up circuit 1302 and pull-down circuit 1303. An inverted input terminal (−) is connected to the connected point of resistors 1311 and 1312.

Differential amplifying circuit 1307 compares the potential of the connected point of pull-up circuit 1302 and pull-down circuit 1303 (VDD/2). If the former potential is higher than the latter potential, the signal level of the output of differential amplifying circuit 1307 is the “H” level. If the latter potential is higher than the former potential, the signal level of the output of differential amplifying circuit 1307 is the “L” level.

When internal command signal ZQACT is inactivated, counter circuits 1304 and 1305 stop counting and hold the current count values.

The count value of counter circuit 1304 is used as impedance control signal DRZQP, the count value of counter circuit 1305 is used as impedance control signal DRZQN, and these signals are output to data input/output circuit 12. Data input/output circuit 12 adjusts the impedance of the output buffer corresponding to impedance control signal DRZQP and impedance control signal DRZQN when data are read from semiconductor device 200Y or when it operates in the on-die-termination mode.

It is apparent that the present invention is not limited to the above embodiments, but may be modified and changed without departing from the scope and spirit of the invention.

1. A semiconductor device comprising:
a voltage comparing circuit including first and second transistors that are coupled in a differential manner to compare first and second input voltages;
an amplifying circuit amplifying an output voltage of the voltage comparing circuit to produce an amplified signal and holding the amplified signal; and
a control circuit configured, when activated, to cut off a current path though which a current flows from the amplifying circuit, the current path including a serial connection of the first and second transistors.

2. The semiconductor device as claimed in claim 1, wherein the control circuit cuts off the current path after the amplifying circuit substantially holds the amplified signal.

3. The semiconductor device as claimed in claim 2, wherein the control circuit comprises a switch inserted in the current path, the switch is turned OFF after the amplifying circuit substantially holds the amplified signal.

4. The semiconductor device as claimed in claim 2, wherein a control circuit supplies a gate of the first transistor with a cut-off voltage which turns the first transistor OFF after the amplifying circuit substantially holds the amplified signal.

5. The semiconductor device as claimed in claim 4, wherein a control circuit further supplies a gate of the second transistor with the cut-off voltage after the amplifying circuit substantially holds the amplified signal.

6. The semiconductor device as claimed in claim 4, wherein a control circuit further supplies a gate of the second transistor with the second input voltage after the amplifying circuit substantially holds the amplified signal.

7. The semiconductor device as claimed in claim 2, wherein the amplifying circuit starts to amplify the output voltage of the voltage comparing circuit after the voltage comparing circuit starts to compare the first and second input voltages.

8. A semiconductor device comprising:
a voltage comparing circuit including first and second transistors that are coupled in a differential manner to compare first and second input voltages;
an amplifying circuit amplifying an output voltage of the voltage comparing circuit to produce an amplified signal and holding the amplified signal; and
a switch circuit inserted in series with at least one of the first and second transistors and configured, when turned OFF, to cut off a current flowing into the at least one of the first and second transistors.

9. The semiconductor device as claimed in claim 8, wherein the switch circuit is turned OFF after the amplifying circuit substantially holds the amplified signal.

10. A semiconductor device comprising:
a voltage comparing circuit including first and second transistors that are coupled in a differential manner to compare first and second input voltages;
an amplifying circuit amplifying an output voltage of the voltage comparing circuit to produce an amplified signal and holding the amplified signal; and
a first control circuit configured, when activated, to supply a gate of the first transistor with a cut-off voltage which turns each of the first and second transistors OFF and, when inactivated, to supply the gate of the first transistor with the first input voltage.

11. The semiconductor device as claimed in claim 10, wherein the first control circuit comprises a first inverter circuit including a power node and input and output nodes, the power node of the first inverter circuit is supplied with the first input voltage, the input node of the first inverter circuit is supplied with a control signal, and the output node of the first inverter circuit is coupled to the gate of the first transistor.

12. The semiconductor device as claimed in claim 11, further comprising a second control circuit configured, when activated, to supply a gate of the second transistor with the cut-off voltage, when inactivated, to supply the gate of the second transistor with the second input voltage.

13. The semiconductor device as claimed in claim 12, wherein the second control circuit comprises a second inverter circuit including a power node and input and output nodes, the power node of the second inverter circuit is supplied with the second input voltage, the input node of the second inverter circuit is supplied with the control signal, and the output node of the second inverter circuit is coupled to the gate of the second transistor.

14. The semiconductor device as claimed in claim 11, further comprising a second control circuit configured to supply a gate of the second transistor with the second input voltage.

15. The semiconductor device as claimed in claim 14, wherein the second control circuit comprises a second inverter circuit including a power node and input and output nodes, the power node of the second inverter circuit is supplied with the second input voltage, the input node of the second inverter circuit is supplied with a power voltage, and the output node of the second inverter circuit is coupled to the gate of the second transistor.

16. The semiconductor device as claimed in claim 10, wherein the first control circuit supplies the gate of the first transistor with the cut-off voltage after the amplifying circuit substantially holds the amplified signal.

17. The semiconductor device as claimed in claim 12, wherein the second control circuit supplies the gate of the second transistor with the cut-off voltage after the amplifying circuit substantially holds the amplified signal.
